(19) United States
(12) Patent Application Publication
(10) Pub. No.: US 2008/0160703 A1
(43) Pub. Date: Jul. 3, 2008

(54) Method for Manufacturing Semiconductor Device

(76) Inventor: Hyun Ju Lim, Mapo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/924,289

(22) Filed: Oct. 25, 2007

(30) Foreign Application Priority Data
Dec. 28, 2006 (KR) 10-2006-0135883

(51) Int. Cl. H01L 21/8234

(52) U.S. Cl. 438/275; 257/E21.616

(57) ABSTRACT

A method for manufacturing a semiconductor device is provided. A first gate can be formed in a salicide region of a semiconductor substrate, and a second gate can be formed in a non-salicide region of the semiconductor substrate. A source and a drain can be formed at both sides of each of the first and second gates. An insulating layer covering the first and second gates can be formed, and first and second spacers can be formed on the insulating layer. The non-salicide region can be covered with a mask, and the insulating layer of the salicide region can be selectively removed. Salicide can then be formed on the first gate, and the source and drain of the first gate.

### CROSS-REFERENCE TO RELATED APPLICATION

The present application claims the benefit under 35 U.S.C. §119 of Korean Patent Application No. 10-2006-0135883, filed Dec. 28, 2006, which is hereby incorporated by reference in its entirety.

### BACKGROUND

As semiconductor device technology develops, semiconductor device performance continues to improve. Particularly, metal oxide semiconductor (MOS) devices become smaller in order to improve the performance of the devices. As MOS devices become smaller, the gate length of a gate electrode (that is, the channel width) decreases. Additionally, the junction depth of source/drain impurity regions becomes shallower. Accordingly, the sheet resistance of the gate electrode and source/drain regions increases.

In order to reduce the sheet resistance of the gate electrode and the source/drain regions, self-aligned silicide (salicide: SAL) is often formed at the gate electrode, the source, and the drain. The salicide help inhibits an increase in the sheet resistance caused by the miniaturization of the semiconductor device.

Semiconductor devices often include regions where salicide is formed and regions where salicide should not be formed.

In order to selectively form salicide only in regions requiring the salicide, a SAL transistor including salicide and a non-SAL (NSAL) transistor not requiring salicide may be formed at a salicide region and a non-salicide region of a semiconductor substrate, respectively. Then, the SAL transistor and the NSAL transistor are each covered with a tetraethyl orthosilicate (TEOS) thin film.

Thereafter, the NSAL transistor including the TEOS thin film is covered with a mask. The TEOS layer covering the SAL transistor and the mask covering the NSAL transistor may be removed through a reactive ion etching (RIE) process and an ashing process, respectively.

Thus, the TEOS layer remains on the NSAL transistor, and the TEOS layer on the SAL transistor is removed.

A salicide process is then performed to form silicide at a gate electrode, a source, and a drain of the SAL transistor.

However, the aforementioned method causes the number of processes for manufacturing a semiconductor device to increase because of a deposition and etching of a TEOS layer. This leads to increased fabrication time and production cost.

Thus, there exists a need in the art for an improved method of fabricating a semiconductor device.

### BRIEF SUMMARY

Embodiments of the present invention provide a method of fabricating a semiconductor device. When gate spacers are formed, an insulating layer can be left behind so that a TEOS layer covering a non-salicided region does not need to be formed later in the fabrication process.

In an embodiment, a method for manufacturing a semiconductor device can include: forming a first gate in a salicide region of a semiconductor substrate; forming a second gate in a non-salicide region of the semiconductor substrate; forming a first source and a first drain at sides of the first gate; forming a second source and a second drain at sides of the second gate; forming a first insulating layer covering the first and second gates; forming a second insulating layer on the first insulating layer; performing an etch-back process to remove a portion of the second insulating layer and to form first and second spacers on the first insulating layer; covering the non-salicide region with a mask; removing the first insulating layer of only the salicide region; and forming salicide on the first gate, the first source, and the first drain.

The details of one or more embodiments are set forth in the accompanying drawings and the detailed description. Other features will be apparent to one skilled in the art from the detailed description, the drawings, and the appended claims.

### BRIEF DESCRIPTION OF THE DRAWINGS

FIGS. 1 to 7 are cross-sectional views illustrating a method of fabricating a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

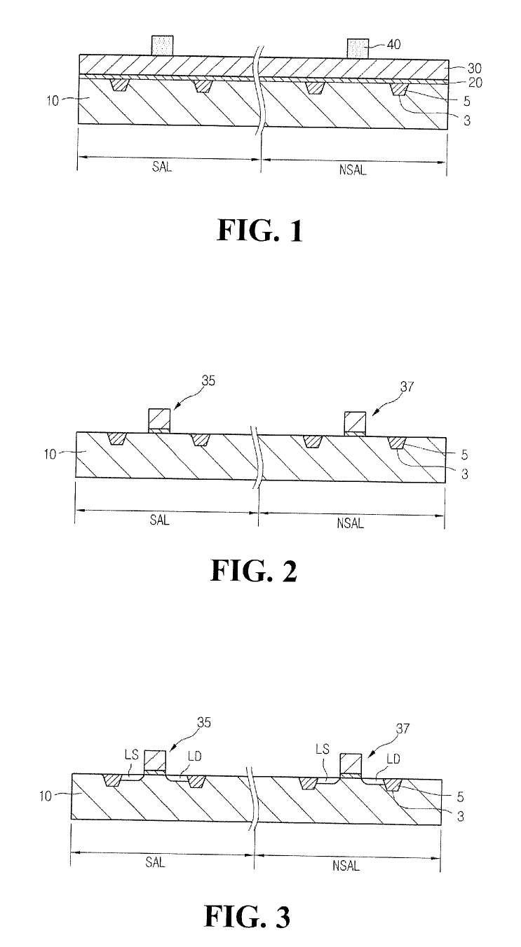

Referring to FIG. 1, device isolation patterns 5 can be formed in a semiconductor substrate 10 including a self-aligned silicide (salicide) region SAL and a non-salicide region NSAL.

To form the device isolation patterns 5, trenches 3 can be formed in the semiconductor substrate 10. Each of the trenches can then be filled with oxide.

After the device isolation patterns 5 are formed, a gate insulating layer 20 can be formed on the semiconductor substrate 10. In an embodiment, the gate insulating layer 20 can be formed by oxidizing the semiconductor substrate 10.

After the gate insulating layer 20 is formed, a polysilicon layer 30 can be formed on the gate insulating layer 20.

A photoresist film (not shown) can be disposed on the polysilicon layer 30. The photoresist film can be patterned to form a photoresist pattern 40 on the polysilicon layer 30. For example, the photoresist film can be patterned by an exposure process and a development process.

Referring to FIG. 2, the polysilicon layer 30 and the gate insulating layer 20 can be patterned using the photoresist patterns 40 as an etching mask to form a first gate 35 and a second gate 37 on the semiconductor substrate 10.

In an embodiment, the first gate 35 can be formed in a salicide region SAL, and the second gate 37 can be formed in a non-salicide region NSAL.

Referring to FIG. 3, impurities can be implanted into the semiconductor substrate 10 using the first gate 35 and the second gate 37 as an ion implantation mask to form a low-concentration source LS and a low-concentration drain LD at sides of the first gate 35 and the second gate 37.

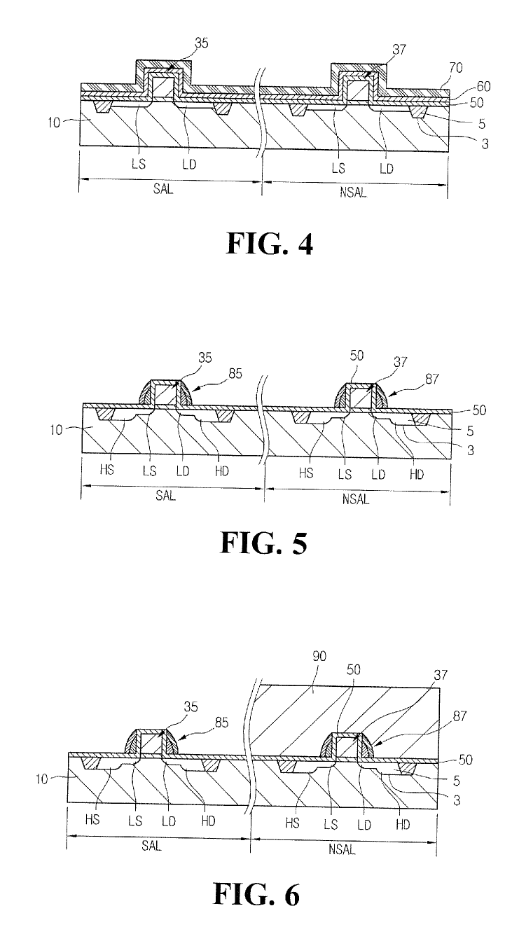

Referring to FIG. 4, after forming the low-concentration sources LS and the low-concentration drains LD, at least one insulating layer c an be formed on the semiconductor substrate 10 covering the first gate 35 and the second gate 37.

For example, a first insulating layer 50, such as an oxide layer, can be formed contacting the first gate 35 and the second gate 37. A second insulating layer 60, such as a nitride layer can be formed on the first insulating layer 50, and a third insulating layer 70, such as another oxide layer can be formed on the second insulating layer 60. In an embodiment, the third insulating layer 70 can be thicker than the first insulating layer 50. In a further embodiment, the first insulating layer 50 can be an oxide layer and can have a thickness of about 150 Å to about 200 Å.

Although the case where three insulating layers are formed is illustrated, in certain embodiments, more or less insulating layers can be formed, for example, one, two, or four insulating layers.

Referring to FIG. 5, the second insulating layer 60 and the third insulating layer 70 can be etched back, so that portions of the first insulating layer 50 covering the first and second gates 35 and 37 can be exposed. In an embodiment where only a first insulating layer and a second insulating layer are formed, the second insulating layer can be etched back to expose portions of the first insulating layer.

In an embodiment, the second insulating layer 60 and the third insulating layer 70 can be etched using an etch-back process. In the etch-back process, hydrogen bromide (HBr) gas, chlorine (Cl₂) gas, and oxygen gas can be used as source gases. The process conditions can include a pressure of about 100 mTorr to about 130 mTorr, a power for dry-etching of about 200 W to about 300 W, a flow rate of Cl₂ gas of about 100 standard cubic centimeters per minute (sccm) to about 150 sccm, a flow rate of HBr gas of about 10 sccm to about 50 sccm, a flow rate of oxygen gas of about 5 sccm to about 10 sccm, and a process time of about 10 seconds to about 50 seconds.

As the second insulating layer 60 and the third insulating layer 70 are etched, a first spacer 85 and a second spacer 87 can be formed on the first insulating layer 50 adjacent to the first gate 35 and the second gate 37, respectively. According to this embodiment, the first insulating layer 50 is not etched during the etching process.

High-concentration impurity ions can be implanted into the semiconductor substrate 10 using the first and second spacers 85 and 87 as an ion implantation mask to form high-concentration sources HS and high-concentration drains HD in the semiconductor substrate 10.

Referring to FIG. 6, after the first and second spacers 85 and 87 are formed, the non-salicide region NSAL can be covered with a mask 90. The non-salicide region NSAL can be covered with the mask 90 in order to remove the first insulating layer 50 covering the first gate 35 of the salicide region SAL while leaving the first insulating layer 50 covering the second gate 37 of the non-salicide region NSAL. Any suitable material known in the art can be used for the mask 90, such as a photoresist. In an embodiment, tetraethyl orthosilicate (TEOS) can be used as the material for the mask 90.

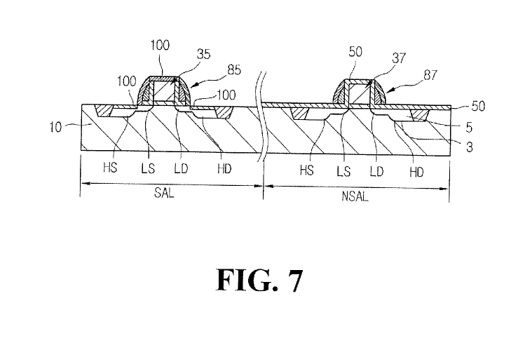

Referring to FIG. 7, the mask (90 in FIG. 6) can be removed by an etching process, for example, a reactive ion etching (RIE) process when formed of TEOS, or an ashing process if formed of a photoresist. Also, a portion of the first insulating layer 50 covering the salicide region SAL can be removed to expose the upper surfaces of the high-concentration source HS of the salicide region SAL, the high-concentration drain HD of the salicide region SAL, and the first gate 35. The portion of the first insulating layer 50 covering the non-salicide region NSAL is not removed.

A silicide metal layer can be deposited on the semiconductor substrate 10 and heat-treated to form silicide 100 on the high-concentration source HS of the salicide region SAL, the high-concentration drain HD of the salicide region SAL, and the first gate 35. The silicide metal layer can be any appropriate material known in the art, for example, a tungsten (W) layer, a titanium (Ti) layer, or a nickel (Ni) layer.

The silicide 100 is not formed in the non-salicide region NSAL because the oxide layer 50 remains on the high-concentration source HS of the non-salicide region NSAL, the high-concentration drain HD of the non-salicide region NSAL, and the second gate 37.

Then, in an embodiment, the remaining silicide metal at portions where no silicide 100 is formed can be removed.

According to embodiments of the present invention, an insulating layer that may not be removed when gate spacers are formed can be removed in a salicide region while remaining in anon-salicide region of a semiconductor device. Accordingly, silicide can be selectively formed only in the salicide region, thereby simplifying a silicide-forming process. Since the insulating layer may not be removed when the gate spacers are formed, the related art method of depositing a thin TEOS film over the entire semiconductor substrate before the salicide process can be avoided. This can decrease fabrication time and lower production costs.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, comprising:
forming a first gate in a salicide region of a semiconductor substrate;
forming a second gate in a non-salicide region of the semiconductor substrate;
forming a first source and a first drain at sides of the first gate;
forming a second source and a second drain at sides of the second gate;
forming a first insulating layer on the semiconductor substrate, including the first gate and the second gate;
forming a second insulating layer on the first insulating layer;
performing an etch-back process to remove a portion of the second insulating layer and form first spacers adjacent to the first gate and second spacers adjacent to the second gate;
covering the non-salicide region with a mask;
removing the first insulating layer from only the salicide region; and
forming salicide on the first gate, the first source, and the first drain.

2. The method according to claim 1, wherein forming the first gate and forming the second gate comprises:
forming a gate insulating layer on the semiconductor substrate;
forming a polysilicon layer on the gate insulating layer; and
patterning the polysilicon layer and the gate insulating layer to form the first gate and the second gate.

3. The method according to claim 1, further comprising forming a third insulating layer on the second insulating layer, wherein the etch-back process further removes a portion of the third insulating layer.

4. The method according to claim 3, wherein the third insulating layer is thicker than the first insulating layer.

5. The method according to claim 3, wherein the third insulating layer is an oxide layer.

6. The method according to claim 5, wherein the first insulating layer is an oxide layer, and wherein the second insulating layer is a nitride layer.

7. The method according to claim 1, wherein process conditions of the etch-back process comprise:
a pressure of about 100 mTorr to about 130 mTorr;
a power of about 200 W to about 300 W;
chlorine (Cl₂) gas provided at a rate of about 100 sccm to about 150 sccm;
HBr gas provided at a rate of about 10 sccm to about 50 sccm;
oxygen gas provided at a rate of about 5 sccm to about 10 sccm; and
a process time of about 10 seconds to about 50 seconds.

8. The method according to claim 1, wherein the mask comprises tetraethyl orthosilicate (TEOS).

9. The method according to claim 1, wherein the mask comprises a photoresist material.

10. The method according to claim 1, wherein removing the first insulating layer from only the salicide region comprises etching the first insulating layer from the salicide region using the mask as an etching mask.

11. The method according to claim 1, wherein forming the salicide comprises:
forming a salicide metal layer on the semiconductor substrate; and
heat-treating the semiconductor substrate.

12. The method according to claim 11, wherein the salicide metal layer comprises tungsten, titanium, or nickel.

13. The method according to claim 1, wherein the first insulating layer has a thickness of about 150 Å to about 200 Å.

14. The method according to claim 1, wherein the first insulating layer is an oxide layer.

15. The method according to claim 1, wherein the second insulating layer is a nitride layer.

16. The method according to claim 1, wherein the etch-back process is performed such that a first portion of the first gate and a second portion of the first insulting layer on the second gate are exposed.
